(19) United States
(12) Patent Application Publication
(10) Pub. No.: US 2015/0083992 A1
(43) Pub. Date: Mar. 26, 2015

(54) GROUP-III NITRIDE SEMICONDUCTOR LIGHT EMITTING ELEMENT, METHOD OF MANUFACTURING THE SAME AND METHOD OF MANUFACTURING MOUNTING BODY

(71) Applicant: TOYODA GOSEI CO., LTD., Kiyosu-shi (JP)

(72) Inventors: Toru Kanto, Kiyosu-shi (JP); Satoshi Wada, Kiyosu-shi (JP)

(21) Appl. No.: 14/462,362

(22) Filed: Aug. 18, 2014

(30) Foreign Application Priority Data
Sep. 20, 2013 (JP) 2013-194999

(51) Int. Cl. H01L 33/24; H01L 33/06; H01L 33/50; H01L 33/00

(52) U.S. Cl. CPC H01L 33/24; H01L 33/007; H01L 33/06; H01L 33/505; H01L 2933/0041
USPC 257/13; 438/29

(57) ABSTRACT

A method of manufacturing a group-III nitride semiconductor light emitting element includes a first irregularity shape part forming process of sequentially forming an n-type semiconductor layer, a light emitting layer and a p-type semiconductor layer on an irregularity substrate to make a laminated body and forming a first irregularity shape part on the n-type semiconductor layer, a first irregularity shape part exposing process of separating the irregularity substrate from the laminated body to expose the first irregularity shape part of the n-type semiconductor layer, and a second irregularity shape part forming process of roughening a surface of the first irregularity shape part of the n-type semiconductor layer to form a second irregularity shape part having fine irregularity on the first irregularity shape part.

### CROSS-REFERENCE TO RELATED APPLICATIONS

This application claims the benefit of Japanese Patent Application No. 2013-194999 (filed on Sep. 20, 2013), the entire contents of which are hereby incorporated by reference.

### BACKGROUND

1. Technical Field

The invention relates to a group-III nitride semiconductor light emitting element having improved light extraction efficiency, a method of manufacturing the same and a method of manufacturing a mounting body.

2. Background Art

In recent years, in order to realize high brightness and high efficiency of a semiconductor light emitting element, it is needed to improve internal quantum efficiency and light extraction efficiency. As a cause of lowering the light extraction efficiency, total reflection of a part of light at an interface between a semiconductor layer and an outside air may be exemplified. When the light is directed from the semiconductor layer having a high refractive index into the outside having a low refractive index, the light of a threshold angle (θc) or larger is totally reflected at an element interface (refer to a paragraph [0003] of JP-A-2009-38407).

For this reason, JP-A-2012-33695 discloses a technology of forming a light extraction surface into an irregularity surface (refer to FIG. 6 and the like of JP-A-2012-33695).

Thereby, the light is not incident with the threshold angle (θc) or larger at the interface between the semiconductor layer and the outside air.

However, in order to manufacture a light emitting element having higher brightness, it is required to further improve the light extraction efficiency.

The invention has been made to solve the above problem of the related art. That is, an object of the invention is to provide a group-III nitride semiconductor light emitting element having improved light extraction efficiency from a light extraction surface, a method of manufacturing the same and a method of manufacturing a mounting body.

### SUMMARY

(1) A method of manufacturing a group-III nitride semiconductor light emitting element includes a first irregularity shape part forming process of sequentially forming an n-type semiconductor layer, a light emitting layer and a p-type semiconductor layer on an irregularity substrate to make a laminated body and forming a first irregularity shape part on the n-type semiconductor layer, a first irregularity shape part exposing process of separating the irregularity substrate from the laminated body to expose the first irregularity shape part of the n-type semiconductor layer, and a second irregularity shape part forming process of roughening a surface of the first irregularity shape part of the n-type semiconductor layer to form a second irregularity shape part having fine irregularity on the first irregularity shape part.

In the method of manufacturing the group-III nitride semiconductor light emitting element, the first irregularity shape part and the fine irregularity shape formed on the surface of the first irregularity shape part are formed on the surface of the n-type semiconductor layer. Therefore, the light extraction efficiency of the semiconductor light emitting element manufactured by the method is sufficiently higher than the light extraction efficiency of the semiconductor light emitting element of the related art. In the meantime, the first irregularity shape part has a shape corresponding to irregularity of an irregularity substrate. The first irregularity shape part is formed on a side of the n-type semiconductor layer facing the irregularity substrate.

(2) In the method according to (1), the first irregularity shape part has a flat part and an inclined part, and the second irregularity shape part forming process includes forming fine irregularity on both the flat part and the inclined part.

(3) The method according to (1) or (2) further includes a fluorescent material containing glass layer forming process of forming a fluorescent material containing glass layer on the first irregularity shape part of the n-type semiconductor layer, and a third irregularity shape part forming process of roughening a surface of the fluorescent material containing glass layer to form a third irregularity shape part on the fluorescent material containing glass layer.

(4) In the method according to any one of (1) to (3), the second irregularity shape part forming process includes roughening the first irregularity shape part by wet etching.

(5) In the method according to (4), the second irregularity shape part farming process includes etching the first irregularity shape part by a TMAH solution or KOH solution.

(6) In the method according to any one of (1) to (5), the first irregularity shape part forming process includes forming a plurality of concave portions, which corresponds to a plurality of convex portions of a convex shape substrate, on the n-type semiconductor layer, and the first irregularity shape part exposing process includes exposing the multiple concave portions of the n-type semiconductor layer.

(7) In the method according to any one of (1) to (6), the first irregularity shape part exposing process includes removing the irregularity substrate by a laser liftoff method.

(8) The method according to any one of (1) to (7) further includes a cleaning process of cleaning the surface of the first irregularity shape part by an HCl solution, wherein the cleaning process is performed before the second irregularity shape part forming process.

(9) A method of manufacturing a mounting body of a group-III nitride light emitting element includes the first irregularity shape part forming process, the first irregularity shape part exposing process and the second irregularity shape part forming process according to any one of (1) to (8), and a mounting process of mounting the laminated body on a sub-mount to make a mounting body, wherein after the mounting process, the first irregularity shape part exposing process and the second irregularity shape part forming process are performed.

(10) A group-III nitride semiconductor light emitting element includes an n-type semiconductor layer, a light emitting layer, and a p-type semiconductor layer. The n-type semiconductor layer includes a first irregularity shape part having a flat part and an inclined part, and the first irregularity shape part has a second fine irregularity shape part on both the flat part and the inclined part.

(11) In the group-III nitride semiconductor light emitting element according to (10), a fluorescent material containing glass layer is provided on the first irregularity shape part and the second irregularity shape part of the n-type semiconductor layer, and the fluorescent material containing glass layer has a third roughened irregularity shape part.

According to the invention, a group-III nitride semiconductor light emitting element having improved light extraction efficiency from a light extraction surface, a method of manufacturing the same and a method of manufacturing a mounting body are provided.

### BRIEF DESCRIPTION OF THE DRAWINGS

FIG. 1 is a schematic configuration view showing a structure of a light emitting element according to a first illustrative embodiment.

FIG. 2 is an enlarged view of an n-type semiconductor layer and a periphery thereof according to the first illustrative embodiment.

FIG. 3 shows an irregularity shape of a growth substrate that is used for a method of manufacturing the light emitting element according to the first illustrative embodiment.

FIG. 4 shows a correspondence relation between the irregularity shape of the growth substrate that is used for the method of manufacturing the light emitting element according to the first illustrative embodiment and an irregularity shape of the n-type semiconductor layer.

FIG. 5 illustrates a method of manufacturing the light emitting element according to the first illustrative embodiment.

FIG. 6 illustrates the method of manufacturing the light emitting element according to the first illustrative embodiment.

FIG. 7 illustrates the method of manufacturing the light emitting element according to the first illustrative embodiment.

FIG. 8 illustrates the method of manufacturing the light emitting element according to the first illustrative embodiment.

FIG. 9 illustrates the method of manufacturing the light emitting element according to the first illustrative embodiment.

FIG. 10 is a schematic configuration view showing a structure of a light emitting element according to a modified embodiment of the first illustrative embodiment.

FIG. 11 is a schematic configuration view showing a structure of a light emitting element according to a second illustrative embodiment.

FIG. 12 illustrates a method of manufacturing the light emitting element according to the second illustrative embodiment.

FIG. 13 illustrates the method of manufacturing the light emitting element according to the second illustrative embodiment.

FIG. 14 illustrates the method of manufacturing the light emitting element according to the second illustrative embodiment.

FIG. 15 illustrates the method of manufacturing the light emitting element according to the second illustrative embodiment.

FIG. 16 is a schematic configuration view showing a structure of a light emitting element according to a third illustrative embodiment.

FIG. 17 illustrates a method of manufacturing the light emitting element according to the third illustrative embodiment.

FIG. 18 illustrates the method of manufacturing the light emitting element according to the third illustrative embodiment.

FIG. 19 is a graph showing a relation between treatment time of a TMAH solution and a total radiant flux in the light emitting elements of embodiments and a comparative example.

### DETAILED DESCRIPTION

Hereinafter, specific illustrative embodiments of a semiconductor light emitting element will be described with reference to the drawings. However, the invention is not limited to the illustrative embodiments. Also, a laminated structure of respective layers and an electrode structure of a light emitting element that will be described later are just exemplary. In particular, a roughened surface is extremely shown. Also, a laminated structure different from the illustrative embodiments is also possible. In the respective drawings, a thickness of each layer is just conceptually shown.

### First Illustrative Embodiment

### 1. Semiconductor Light Emitting Element

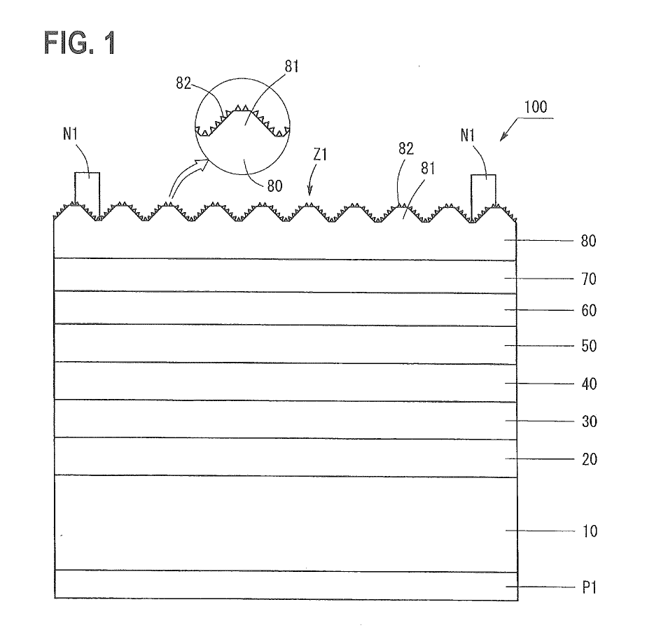

A group-III nitride semiconductor light emitting element of this illustrative embodiment is described. FIG. 1 is a schematic configuration view showing a structure of a light emitting element 100 according to a first illustrative embodiment. The light emitting element 100 is a semiconductor light emitting element consists of a group-III nitride semiconductor. Also, the light emitting element 100 is formed by a laser liftoff method of removing a growth substrate with laser. For this reason, the growth substrate such as a sapphire substrate does not remain on the light emitting element 100. A light extraction surface Z1 exists at an n-type semiconductor layer 80-side.

As shown in FIG. 1, the light emitting element 100 is formed by sequentially arranging a p-type electrode P1, a support substrate 10, a first conductive metal layer 20, a conductive bonding material layer 30, a second conductive metal layer 40, a conductive reflective film 50, a p-type semiconductor layer 60, a light emitting layer 70, an n-type semiconductor layer 80 and an n-type electrode N1 in corresponding order.

The p-type electrode P1 has a Pt layer, a Ti layer, a Pt layer, a Ti layer and an Au layer, which are formed from the support substrate 10 in corresponding order. This is just exemplary and the other laminated structures are also possible.

The support substrate 10 is a support member for holding a shape of the light emitting element 100. Also, the support substrate is to prevent deformation of the light emitting element 100 and to increase a mechanical strength of the light emitting element 100. The support substrate 10 is made of Si. Alternatively, the support substrate may be made of GaAs, Ge and the other metal materials. After the light emitting element 100 is made, it is necessary to supply current to the light emitting layer. For this reason, the support substrate 10 is necessarily made of a conductive material.

The first conductive metal layer 20 is to improve adhesiveness of the support substrate 10 and the conductive bonding material layer 30. The first conductive metal layer 20 may be made of Au, for example.

The conductive bonding material layer 30 is a layer including a bonding material for bonding a formed semiconductor layer and the support substrate 10 in a manufacturing process of the light emitting element 100. After the light emitting element 100 is made, it is necessary to supply current to the light emitting layer. For this reason, the conductive bonding material layer 30 is necessarily made of a conductive material. Specifically, an AuSn-based soldering material may be used. The other soldering alloy is also possible.

The second conductive metal layer 40 is to improve adhesiveness the conductive bonding material layer 30 and the conductive reflective film 50. The second conductive metal layer 40 also has a function of preventing the soldering material of the conductive bonding material layer 30 from diffusing into the semiconductor layer. The second conductive metal layer 40 may be made of Au, for example.

The conductive reflective film 50 is a film for reflecting light generated by the light emitting layer 70. Also, the conductive reflective film 50 has conductivity. This is to enable the sufficient current to flow to the light emitting layer 70 of the light emitting element 100. To this end, the conductive reflective film 50 has both reflectivity of reflecting light and conductivity enabling the current to flow.

The conductive reflective film 50 is made of Ag, Al or alloy including Al or Ag as a main component. Alternatively, rhodium (Rh), ruthenium (Ru), platinum (Pt) or alloy including at least one of the metals is also possible. Alternatively, a distributed Bragg reflective film formed by a plurality of layers of two materials having different refractive indexes is also possible.

The p-type semiconductor layer 60 is to trap electrons. That is, the p-type semiconductor layer 60 is to prevent the electrons from diffusing towards the conductive reflective film 50. Thereby, it is possible to improve the light emitting efficiency in the light emitting layer 70.

The light emitting layer 70 is a layer in which an electron and a hole are combined to emit the light. To this end, the light emitting layer 70 has a multi quantum well structure in which a well layer having a small band gap and a barrier layer having a large band gap are alternately formed. Here, the well layer is an InGaN layer and the barrier layer is an AlGaN layer. Also, the well layer may be a GaN layer and the barrier layer may be the AlGaN layer. Alternatively, the barrier layer may be an AlInGaN layer. Alternatively, the above layers may be freely combined to form a unit structure of four or more layers and the unit structure may be repeated. Also, a SQW layer may be used as the light emitting layer. The above is just exemplary and the other materials or structures are also possible.

The n-type semiconductor layer 80 is a contact layer that is contacted to the n-type electrode N1 and is a layer for preventing stress from being applied to the light emitting layer 70. Also, the n-type semiconductor layer 80 is to prevent In of the light emitting layer 70 from diffusing. An Si concentration thereof is 1×10¹⁸/cm³ or larger. The details thereof will be described later.

The n-type electrode N1 is formed on the n-type semiconductor layer 80. That is, the n-type electrode N1 and the n-type semiconductor layer 80 are conductively connected to each other. The n-type electrode N1 is a metallic electrode and is not transparent in general.

### 2. Shape of n-Type Semiconductor Layer

### 2-1. First Irregularity Shape Part

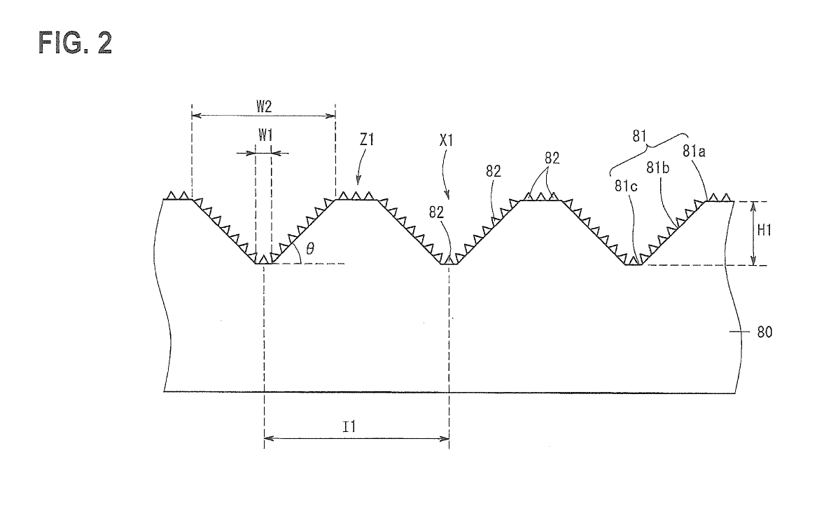

The n-type semiconductor layer 80 has the light extraction surface Z1. FIG. 2 is an enlarged view of the light extraction surface Z1 and a periphery thereof of the light emitting element 100. The n-type semiconductor layer 80 has a first irregularity shape part 81. The first irregularity shape part 81 has a flat surface 81a, an inclined surface 81b and a flat surface 81c. Like this, the first irregularity shape part 81 has the flat part and the inclined surface. The n-type semiconductor layer 80 has a plurality of concave portions X1. The concave portion X1 has the flat surface 81c that is a bottom surface and the inclined surface 81b surrounding the flat surface 81c. The concave portion X1 of the first irregularity shape part 81 is formed in correspondence to irregularity of the growth substrate, which will be described later.

The flat surface 81a, the inclined surface 81b and the flat surface 81c have second irregularity shape parts 82, respectively. The second irregularity shape parts 82 are formed resulting from roughening by a wet etching, which will be described later. That is, the first irregularity shape part 81 of the n-type semiconductor layer 80 has the second irregularity shape parts 82 of which the irregularity is fine. The flat part and the inclined surface of the first irregularity shape part 81 are formed with fine irregularities.

### 2-2. Light Emitting Efficiency

In this way, the light extraction surface Z1 of the light emitting element 100 has the first irregularity shape part 81 and the second irregularity shape parts 82 that are the fine irregularity formed on the first irregularity shape part 81. For this reason, the light generated from the light emitting layer 70 is little illuminated to the light extraction surface Z1 at a large incident angle. Thus, the light is little totally reflected at a boundary surface between the n-type semiconductor layer 80 and the element outside. That is, the light extraction efficiency of the light emitting element 100 is improved, as compared to the light emitting element of the related art. A degree of the improvement will be described later.

Here, as shown in FIG. 2, a depth H1 of the concave portion X1 is 1 μm or larger and 2 μm or smaller. A pitch interval of the concave portion X1 is 3 μm or larger and 5 μm or smaller, more preferably, 3 μm or larger and 4 μm or smaller. A width W1 of the flat surface 81c, which is a bottom surface of the concave portion X1, is 0 μm or larger and 0.5 μm or smaller, more preferably, 0.05 μm or larger and 0.3 μm or smaller. A width W2 of an upper surface of the concave portion X1 is 2 μm or larger and 4 μm or smaller, more preferably 2.7 μm or larger and 3.3 μm or smaller. An angle between the flat surface 81c and the inclined surface 81b is 45° or larger and 60° or smaller, more preferably 50° or larger and 60° or smaller.

### 3. Growth Substrate (Irregularity Substrate)

### 3-1. Shape of Growth Substrate

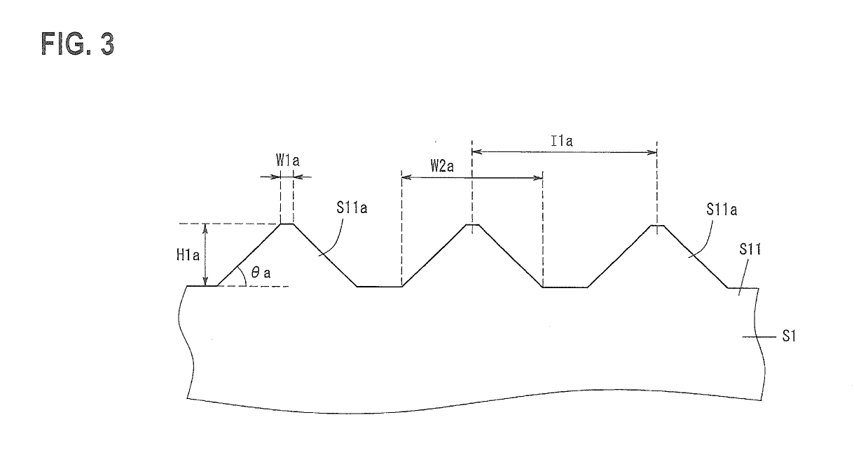

FIG. 3 shows a growth substrate that is used for a method of manufacturing the light emitting element of this illustrative embodiment. The sapphire substrate S1 shown in FIG. 3 is a growth substrate having an irregularity shape S11 on a principal surface. Specifically, the irregularity shape S11 has a plurality of convex portions S11a. The material of the growth substrate is not limited to sapphire.

### 3-2. Correspondence Relation Between Shape of Irregularity Substrate and Shape of n-Type Semiconductor Layer

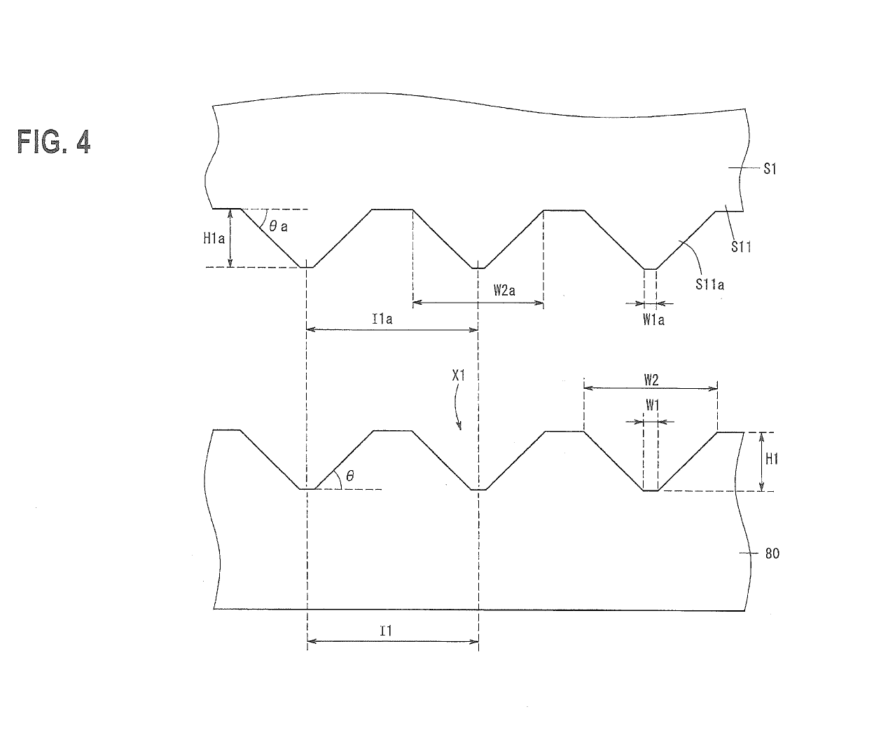

FIG. 4 shows a correspondence relation between the shape of the sapphire substrate S1 and the shape of the n-type semiconductor layer 80. As shown in FIG. 4, the convex portion S11a of the sapphire substrate S1 and the concave portion X1 of the n-type semiconductor layer 80 have shapes corresponding to each other. Therefore, the convex portion S11a of the sapphire substrate S1 can be concisely matched with the concave portion X1 of the n-type semiconductor layer 80.

However, as described later, since the sapphire substrate S1 is removed from the n-type semiconductor layer 80 by using the laser liftoff method and the like, a damage is somewhat caused in the n-type semiconductor layer 80. For this reason, actually, the convex portion S11a of the sapphire substrate S1 and the concave portion X1 of the n-type semiconductor layer 80 have shapes slightly deviating from each other.

Accordingly, a height H1a of the convex portion S11a is substantially the same as the depth H1 of the concave portion X1. A pitch interval 11a of the convex portion S11a is substantially the same as the pitch interval I1 of the concave portion X1. A width W1a of an apex of the convex portion S11a is substantially the same as the width W1 of the flat surface 81c of the concave portion X1. A width W2a of a bottom of the convex portion S11a is substantially the same as the width W2 of the upper surface of the concave portion X1.

### 4. Method of Manufacturing Semiconductor Light Emitting Element

In a method of manufacturing the semiconductor light emitting element of this illustrative embodiment, crystals of the respective layers are epitaxially grown by a metalorganic chemical vapor deposition (MOCVD) method. In the below, respective processes are described.

### 4-1. Semiconductor Layer Foal ing Process (First Irregularity Shape Part Forming Process)

In this illustrative embodiment, the sapphire substrate S1 having the irregularity shape formed on the principal surface is used as the growth substrate. The sapphire substrate S1 is put into a MODVD furnace. Then, the sapphire substrate S1 is cleaned in a hydrogen gas, so that matters attached on the surface of the sapphire substrate S1 are removed. Then, a low-temperature buffer layer B1 is formed on the sapphire substrate S1.

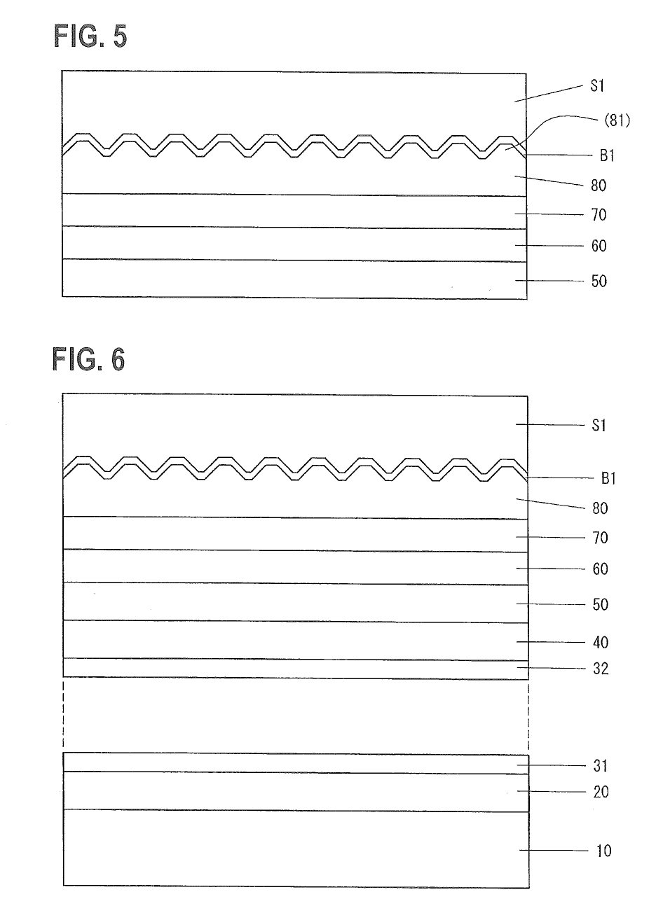

Then, as shown in FIG. 5, the n-type semiconductor layer 80 is grown on the low-temperature buffer layer B1. Subsequently, the light emitting layer 70 is faulted on the n-type semiconductor layer 80. Then, the p-type semiconductor layer 60 is formed on the light emitting layer 70. Then, the conductive reflective film 50 is formed on the p-type semiconductor layer 60. In the meantime, when growing the n-type semiconductor layer 80, the first irregularity shape part 81 is fainted.

### 4-2. Bonding Layer Forming Process

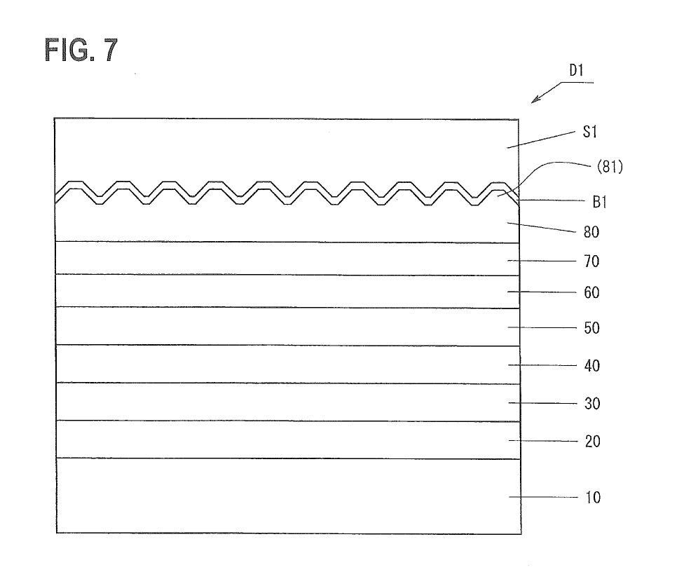

Then, as shown in FIG. 6, the second conductive metal layer 40 and a low-melting point metal layer 32 are formed in corresponding order on the conductive reflective film 50. In the meantime, the first conductive metal layer 20 and a low-melting point metal layer 31 are formed in corresponding order on the support substrate 10. The low-melting point metal layer 31 formed at the support substrate 10-side and the low-melting point metal layer 32 formed at the sapphire substrate S1-side are made to confront each other. Then, the low-melting point metal layer 31 and the low-melting point metal layer 32 are bonded. Here, the low-melting point metal layers 31, 32 are soldering materials. Then, the low-melting point metal layers 31, 32 become the integrated conductive bonding material layer 30. Thereby, a laminated body D1 as shown in FIG. 7 is obtained.

### 4-3. Growth Substrate Separating Process (First Irregularity Shape Part Exposing Process)

Subsequently, the laser is illuminated to the principal surface of the sapphire substrate S1 of the laminated body D1 shown in FIG. 7. The laser that is here illuminated is KrF high-power pulse laser having a wavelength of 248 nm. Also, any of YAG laser (355 nm, 266 nm), XeCl laser (308 nm), ArF laser (155 nm) and the like may be used. The other laser is also used as long as it has a wavelength shorter than 365 nm.

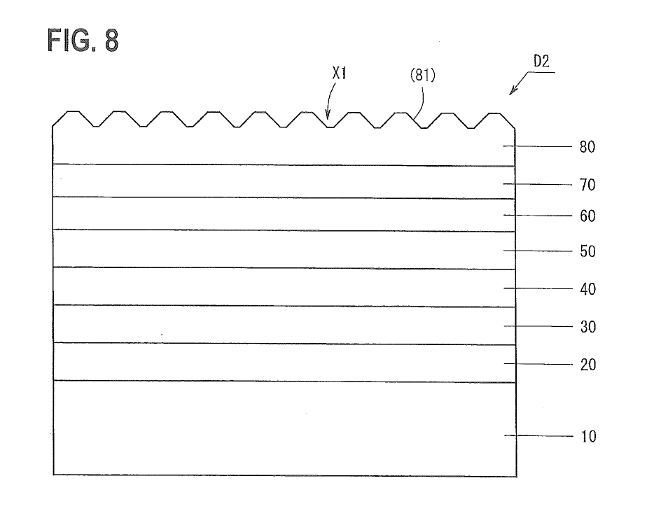

Thereby, the sapphire substrate S1 can be separated from the laminated body D1 of FIG. 7. By this separation, the first irregularity shape part 81 of the n-type semiconductor layer 80 is exposed. Thereby, a laminated body D2 of FIG. 8 is manufactured. As shown in FIG. 8, at this stage, a plurality of concave portions X1 is exposed. In the meantime, the low-temperature buffer layer B1 is thin. Therefore, at least a part of the low-temperature buffer layer B1 is removed together with the sapphire substrate S1 by the growth substrate separating process.

As shown in FIG. 8, at this stage, the first irregularity shape part 81 is formed on the surface of the n-type semiconductor layer 80. As described above, the first irregularity shape part 81 corresponds to the irregularity shape S11 of the sapphire substrate S1. However, at this stage, the second irregularity shape part 82 having fine irregularity is not formed yet.

### 4-4. Cleaning Process

Then, the surface of the first irregularity shape part 81 of the n-type semiconductor layer 80 is cleaned. Specifically, an HCl aqueous solution is used. A concentration of the aqueous solution is 17% or larger and 34% or smaller. Thereby, the low-temperature buffer layer B1, which has not been removed by the laser, is removed.

### 4-5. Etching Process (Second Irregularity Shape Part Forming Process)

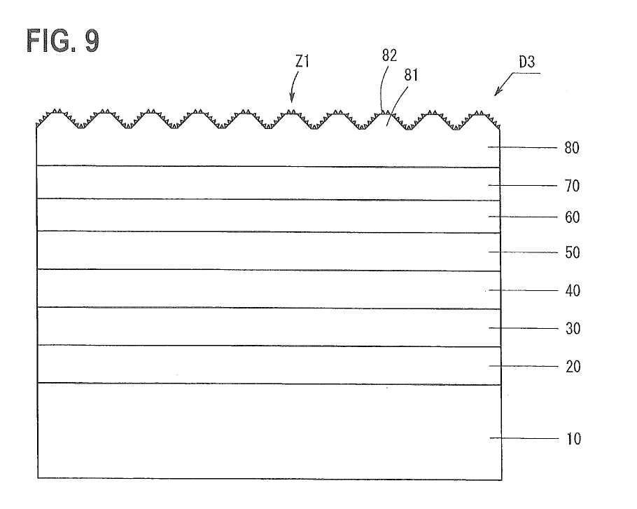

Subsequently, the first irregularity shape part 81 of the n-type semiconductor layer 80 is formed with the second irregularity shape parts 82 having fine irregularity. To this end, the surface of the first irregularity shape part 81 is roughened by wet etching. Specifically, the surface of the n-type semiconductor layer 80 is immersed into a TMAH solution. A temperature of the TMAH solution is within a range of 20° C. or higher and 80° C. or lower. The temperature of the TMAH solution is preferably 60° C. A concentration of the TMAH solution is within a range of 20% or higher and 60% or lower. The etching time is preferably 3 minutes or longer, as described later. By the etching, the second irregularity shape parts 82 are formed. Instead of the TMAH solution, a potassium hydroxide (KOH) aqueous solution may be used. A laminated body D3 after the fine irregularity is formed is shown in FIG. 9. As shown in FIG. 9, the first irregularity shape part 81 has the second irregularity shape parts 82.

### 4-6. Electrode Forming Process

Subsequently, the p-type electrode P1 is formed on a surface of the support substrate 10, which is opposite to the first conductive metal layer 20. As the p-type electrode P1, a Pt layer, a Ti layer, a Pt layer, a Ti layer and an Au layer are formed in corresponding order from the support substrate 10. Also, the n-type electrode N1 is formed on the n-type semiconductor layer 80. As the n-type electrode N1, a W layer, a Ti layer and an Au layer are formed in corresponding order from the n-type semiconductor layer 80. By the above processes, the light emitting element 100 shown in FIG. 1 is manufactured.

### 5. Modified Embodiments

### 5-1. Protective Film

In this illustrative embodiment, the n-type semiconductor layer 80 is exposed. However, a protective film that covers the first irregularity shape part 81 of the n-type semiconductor layer 80 may be formed. To this end, a sputter apparatus may be used. The protective film is transparent. As the protective film, SiO₂ may be used. SiO₂ is a dielectric material. Also, as the protective film, Si₃N₄ or SiO_{2X}N_{4Y} (X+3Y=1) may be used. Also, the protective film has an irregularity shape corresponding to the first irregularity shape part 81. However, an inclination of an inclined surface of the protective film is slightly gentler, as compared to the first irregularity shape part 81.

### 5-2. Conductive Protective Film

Furthermore, the protective film is preferably made of a conductive material. This is to enable the current to diffuse in a plane direction (a horizontal direction in FIG. 1) of the semiconductor layer, thereby effectively supplying the current over a light emitting area of the light emitting layer. In this case, since the protective film is conductive, the n-type electrode N1 is preferably formed on the protective film. By doing so, most of the first irregularity shape part 81 of the n-type semiconductor layer 80 is covered as much as possible, so that the current diffuses into the light emitting layer 70 in the plane direction. Here, as the conductive transparent material, indium tin oxide (ITO) may be used. Alternatively, ICO, IZO, ZnO, TiO₂, NbTiO₂, TaTiO₂ or the like may be used.

### 5-3. Substrate Peeling-off Method

In this illustrative embodiment, the sapphire substrate S1 that is the growth substrate is removed from the semiconductor layer by the laser liftoff method. However, instead of using the laser, the etching may be used to peel off the sapphire substrate S1 from the n-type semiconductor layer 80 of the laminated body D1. Also in this case, the sapphire substrate S1 can be removed. The other known methods may be also used to remove the sapphire substrate S1.

### 5-4. Etching Process (Second Irregularity Shape Part Forming Process)

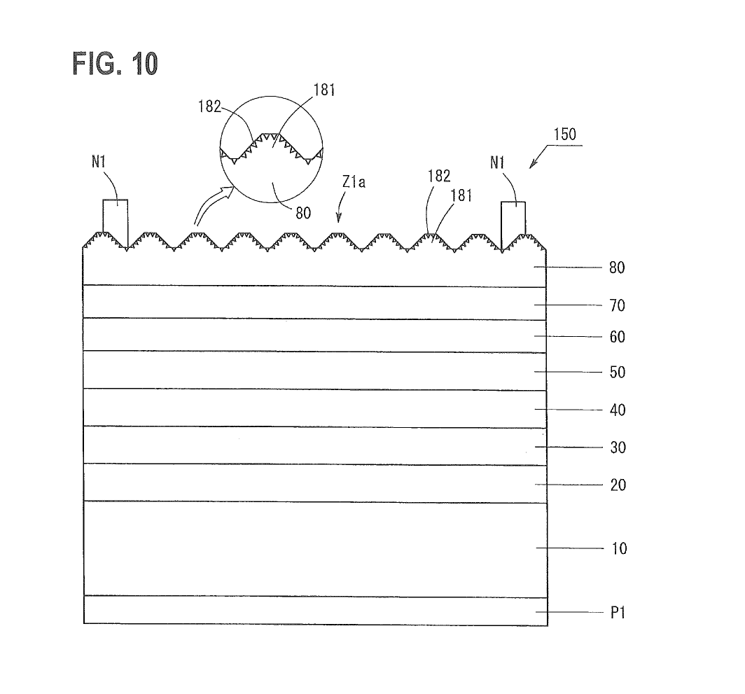

In this illustrative embodiment, the second irregularity shape parts 82 as shown FIG. 2 and the like are formed by the fine irregularity forming process. In FIG. 2, the second irregularity shape part 82 is shown as a convex shape. However, as shown in FIG. 10, a light emitting element 150 having a concave shape is also possible. That is, a first irregularity shape part 181 has second irregularity shape parts 182. The second irregularity shape parts 182 are concave portions.

### 5-5. Conductive Transparent Film

Also, a conductive transparent film may be formed between the p-type semiconductor layer 60 and the conductive reflective film 50. The conductive transparent film is made of ITO, IZO or the like. The conductive transparent film is a layer for ohmic contact with the p-type semiconductor layer 60.

### 5-6. Cleaning Process

In this illustrative embodiment, the cleaning process is performed. However, the cleaning process may be omitted.

### 6. Summary of First Illustrative Embodiment

As specifically described above, the light emitting element 100 of this illustrative embodiment is formed with the first irregularity shape part 81 corresponding to the irregularity of the growth substrate, and the first irregularity shape part is formed with the second fine irregularity shape parts 82. For this reason, the light extraction efficiency of the light emitting element 100 is high.

In the meantime, this illustrative embodiment is just exemplary and is not construed to limit the invention. Therefore, the invention can be variously improved and modified without departing from the gist thereof. The laminated structure of the laminated body is not limited to the structure shown in the drawings. The laminated structure, the repeating number of times of the respective layers and the like may be arbitrarily selected. Also, the invention is not limited to the metalorganic chemical vapor deposition (MOCVD) method. The other crystal growth methods may be also used.

### Second Illustrative Embodiment

### 1. Semiconductor Light Emitting Element

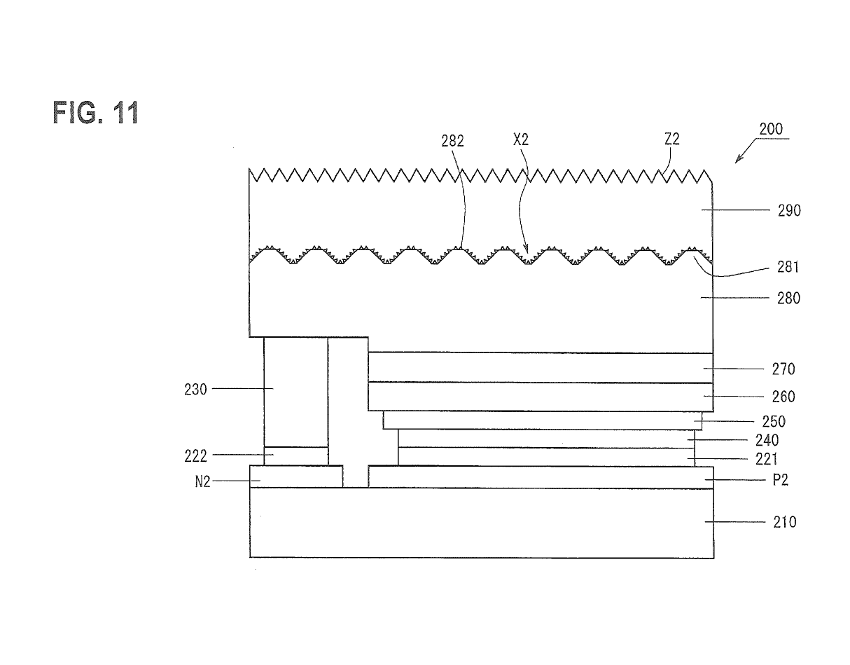

A second illustrative embodiment is described. A light emitting element 200 of this illustrative embodiment is manufactured by the laser liftoff method. As shown in FIG. 11, the light emitting element 200 has a support substrate 210, an n-type electrode N2, a soldering bonding layer 222, a metal layer 230, a p-type electrode P2, a soldering bonding layer 221, a reflective layer 240, a transparent electrode layer 250, a p-type semiconductor layer 260, a light emitting layer 270, an n-type semiconductor layer 280 and a fluorescent material containing glass layer 290.

Here, the soldering bonding layer 221 is to soldering-bond the p-type electrode P2 and the reflective layer 240. The soldering bonding layer 222 is to soldering-bond the n-type electrode N2 and the metal layer 230. Here, a refractive index of the fluorescent material containing glass layer 290 is about 1.3 to 2.1. In order to form the fluorescent material containing glass layer 290, a CVD method, a sputtering method, a heating process and the like may be used.

The reflective layer 240 may be made of the same material as the conductive reflective film 50 of the first illustrative embodiment. The transparent electrode layer 250 may be made of the same material as the conductive transparent film described in the modified embodiment of the first illustrative embodiment. These are just exemplary and the other materials can be also used.

### 2. Fluorescent Material Containing Glass Layer

In this illustrative embodiment, the n-type semiconductor layer 280 has a first irregularity shape part 281. The first irregularity shape part 281 has a plurality of concave portions X2. The concave portion X2 is substantially the same as the concave portion X1 of the n-type semiconductor layer 80 of the light emitting element 100 of the first illustrative embodiment. That is, the concave portion X2 has a plurality of fine irregularity shapes. That is, the first irregularity shape part 281 has second irregularity shape parts 282 of which irregularity is fine.

The fluorescent material containing glass layer 290 is formed on the first irregularity shape part 281 and the second irregularity shape parts 282. A surface of the fluorescent material containing glass layer 290 is a third roughened irregularity shape part. The third irregularity shape part, i.e., the surface of the fluorescent material containing glass layer 290 is a light extraction surface Z2 of the light emitting element 200. In the light emitting element 200, the n-type semiconductor layer 280 is contacted to the fluorescent material containing glass layer 290. For this reason, a refractive index of the n-type semiconductor layer 280 is about 2.5. A refractive index of the fluorescent material containing glass layer 290 is sufficiently larger than 1. Thus, a difference between the refractive indexes of the n-type semiconductor layer 280 and the fluorescent material containing glass layer 290 is smaller than a difference between the refractive indexes of the n-type semiconductor layer 280 and the outside air. Therefore, as described later, the light emitting efficiency is improved.

### 3. Method of Manufacturing Semiconductor Light Emitting Element

### 3-1. Semiconductor Layer Forming Process (First irregularity Shape Part Forming Process)

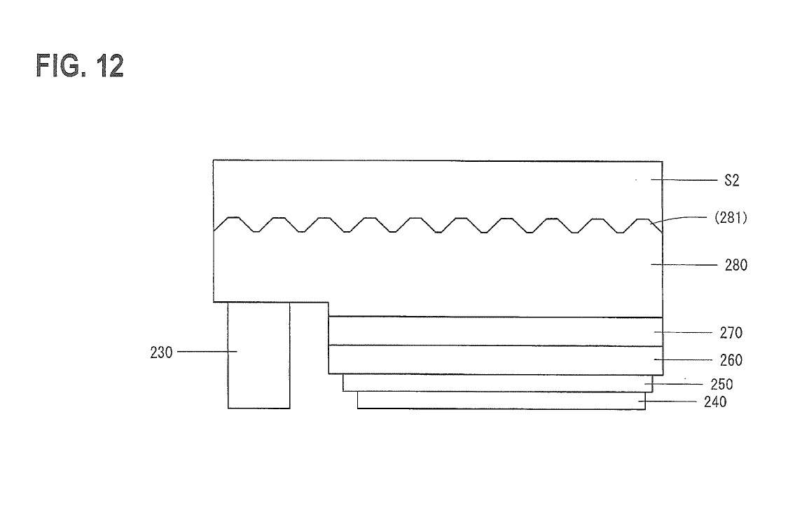

Here, a method of manufacturing the light emitting element 200 is described. First, as shown in FIG. 12, the n-type semiconductor layer 280, the light emitting layer 270 and the p-type semiconductor layer 260 are formed in corresponding order on a sapphire substrate S2 having an irregularity shape. Then, a non-through hole is formed from the p-type semiconductor layer 260 to the n-type semiconductor layer 280, so that a part of the n-type semiconductor layer 280 is exposed. Then, the metal layer 230 is formed on the exposed n-type semiconductor layer 280. In the meantime, the transparent electrode layer 250 is formed on the p-type semiconductor layer 260. The reflective layer 240 is formed on the transparent electrode layer 250.

### 3-2. Bonding Process

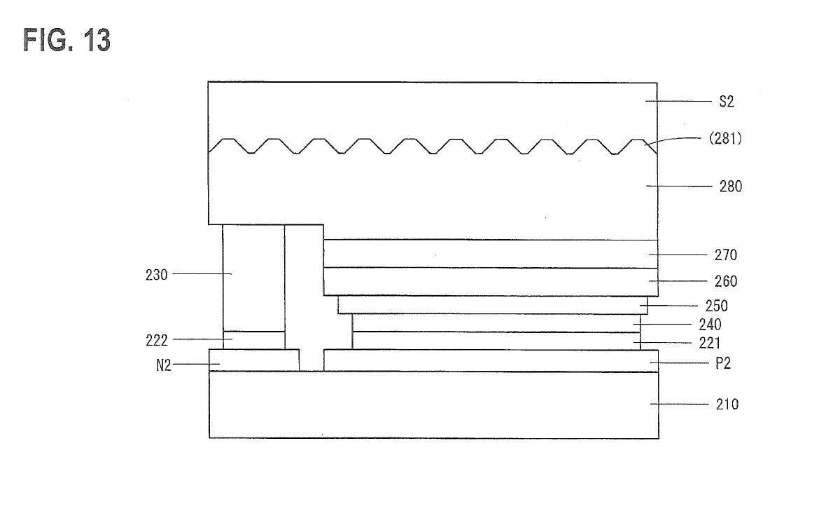

Subsequently, as shown in FIG. 13, a laminated body having the p-type electrode P2 and n-type electrode N2 formed on the support substrate 210 and a laminated body having a semiconductor layer formed thereto are soldering-bonded. Thereby, the p-type electrode P2 is bonded to the reflective layer 240 through the soldering bonding layer 221. Also, the n-type electrode N2 is bonded to the metal layer 230 through the soldering bonding layer 222.

### 3-3. Growth Substrate Separating Process (First irregularity Shape Part Exposing Process)

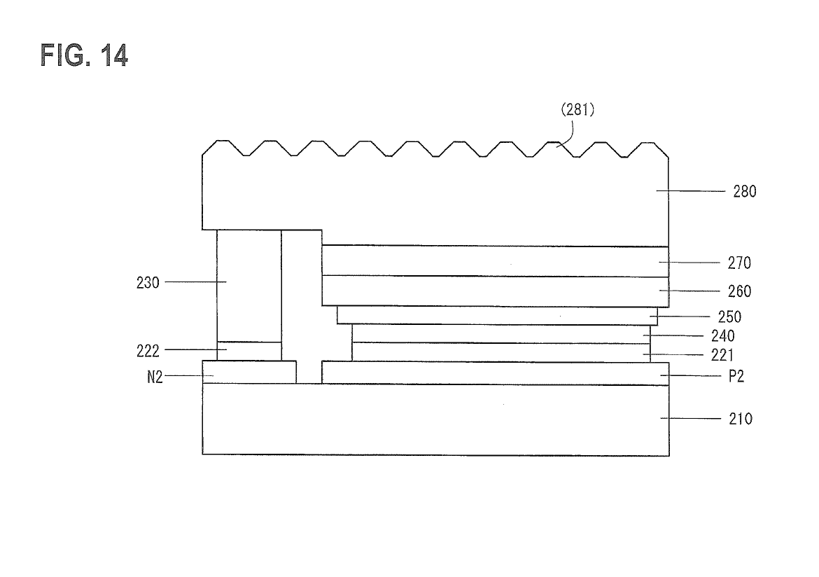

Subsequently, the sapphire substrate S2 is removed from the laminated body by the laser liftoff method. An aspect after the sapphire substrate S2 is removed is shown in FIG. 14. As shown in FIG. 14, the n-type semiconductor layer 280 has the first irregularity shape part 281 on the surface thereof. The first irregularity shape part 281 has a shape corresponding to the irregularity shape of the sapphire substrate S2.

### 3-4. Etching Process (Second irregularity Shape Part Forming Process)

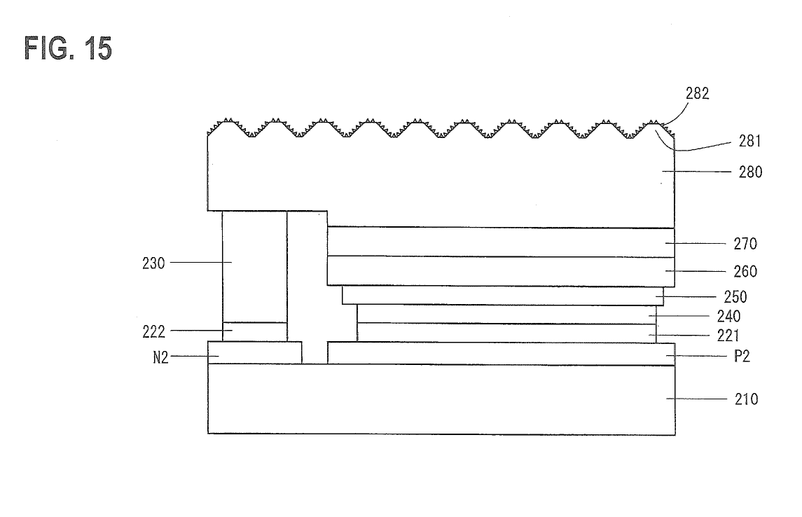

Then, the surface of the first irregularity shape part 281 is roughened. Thereby, the first irregularity shape part 281 is further formed with the second irregularity shape parts 282 that are the fine irregularity. The laminated body after this process is shown in FIG. 15. The first irregularity shape part 281 has the second irregularity shape parts 282 of which irregularity is fine.

### 3-5. Fluorescent Material Containing Glass Layer Forming Process

Then, the fluorescent material containing glass layer 290 is formed on the first irregularity shape part 281 of the n-type semiconductor layer 280. The fluorescent material containing glass layer 290 contains therein a fluorescent material.

### 3-6. Roughening Process (Third Irregularity Shape Part Forming Process)

Subsequently, the surface of the fluorescent material containing glass layer 290 is roughened by the etching. The surface may be also roughened by a transfer or harsh grinding. Thereby, the surface of the fluorescent material containing glass layer 290 is roughened. Thereby, the surface of the fluorescent material containing glass layer 290 is formed with the third irregularity shape part. The third irregularity shape part is the light extraction surface Z2.

### 4. Modified Embodiments

The modified embodiments described in the first illustrative embodiment may be used.

### 5. Summary of Second Illustrative Embodiment

As specifically described above, the light emitting element 200 of this illustrative embodiment is formed with the first irregularity shape part 281 corresponding to the irregularity of the growth substrate, and the first irregularity shape part 281 is formed with the second fine irregularity shape parts 282. For this reason, the light extraction efficiency from the semiconductor layer is high. Also, the fluorescent material containing glass layer 290 is formed on the second fine irregularity shape parts 282. Therefore, white light is extracted from the light emitting element 200 and the light efficiency of the light emitting element 200 is high.

### Third Illustrative Embodiment

### 1. Mounting Body

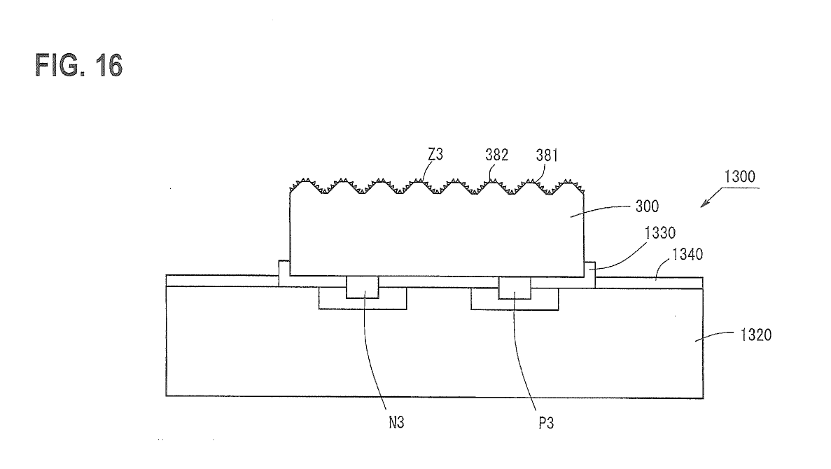

A third illustrative embodiment is described. In a mounting body 1300 of this illustrative embodiment, a light emitting element 300 is mounted on a sub-mount 1320. As shown in FIG. 16, the mounting body 1300 has the light emitting element 300, the sub-mount 1320, a resin layer 1330 and a resin layer 1340. The light emitting element 300 has a light extraction surface Z3 at the n-type semiconductor layer-side.

### 2. Method of Manufacturing Mounting Body

In this illustrative embodiment, after the light emitting element 300 is mounted on the sub-mount 1320, a surface of the n-type semiconductor layer is roughened.

### 2-1. Element Manufacturing Process (First Irregularity Shape Part Forming Process)

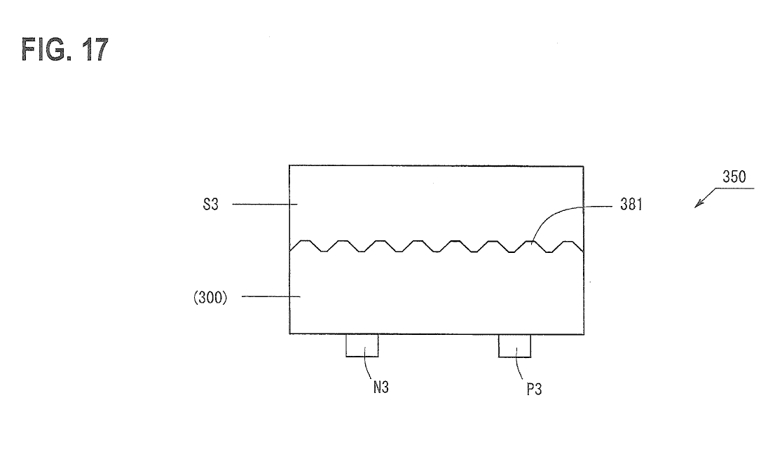

First, a light emitting element 350 shown in FIG. 17 is manufactured. To this end, a semiconductor layer, a p-type electrode P3 and an n-type electrode N3 are formed on a sapphire substrate S3. The sapphire substrate S3 is formed with the irregularity shape. Then, a plurality of elements faulted on a wafer is separated. Thereby, the light emitting element 350 is prepared. In the meantime, at this stage, a surface of the n-type semiconductor layer of the light emitting element 350 is not roughed yet.

### 2-2. Mounting Process

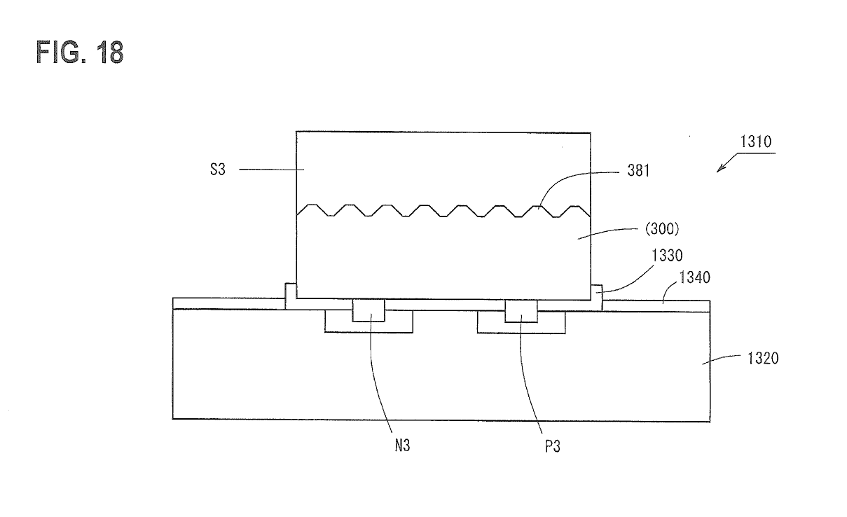

Subsequently, the light emitting element 350 is mounted on the sub-mount 1320. The sub-mount 1320 has the resin layer 1340. An underfill material is injected between the sub-mount 1320 and the light emitting element 350. The underfill material is cured after predetermined time. Then, the underfill material becomes the resin layer 1330. Thereby, a mounting body 1310 of FIG. 18 is manufactured.

### 2-3. Growth Substrate Separating Process (First Irregularity Shape Part Exposing Process)

After the mounting process, the sapphire substrate S3 is removed from the mounting body 1310. To this end, the laser liftoff method is preferably used. Thereby, a first irregularity shape part 381 of the n-type semiconductor layer is exposed.

### 2-4. Cleaning Process

Subsequently, the first irregularity shape part 381 of the n-type semiconductor layer is cleaned using the HCl aqueous solution.

### 2-5. Etching Process (Second Irregularity Shape Part Forming Process)

Subsequently, the exposed first irregularity shape part 381 of the n-type semiconductor layer is etched. To this end, the TMAH solution is preferably used. Also, the KOH solution may be used. Thereby, the first irregularity shape part 381 is formed with fine irregularity. Thus, after this process, the first irregularity shape part 381 has second irregularity shape parts 382 of which irregularity is fine. By the above processes, the mounting body 1300 is manufactured.

### 3. Modified Embodiments

The modified embodiments described in the first illustrative embodiment may be used. Also, like the second illustrative embodiment, a fluorescent material containing glass layer may be formed on the first irregularity shape part 381 of the n-type semiconductor layer.

### 4 Summary of Third Illustrative Embodiment

As specifically described above, the light emitting element 300 of this illustrative embodiment is mounted on the sub-mount 1320. The light emitting element 300 is formed with the first irregularity shape part 381 corresponding to the irregularity of the growth substrate, and the first irregularity shape part 381 is formed with the second fine irregularity shape parts 382. Also, the light emitting element 300 is roughened on the light extraction surface thereof after it is mounted on the sub-mount 1320. Therefore, the light extraction efficiency from the semiconductor layer is high.

### Embodiments

### 1. Growth Substrate (Irregularity Substrate)

Here, an embodiment is described. In this illustrative embodiment, an irregularity substrate on which a plurality of convex shapes is repeatedly arranged was used. The substrate was made of sapphire. As shown in FIG. 3, the pitch interval I1a was 4 μm. A diameter W1a of the apex of the convex portion was 0.2 μm. A diameter W2a of the base of the convex portion was 3 μm. A height H1a of the convex portion was 1.5 μm. An angle θa between the principal surface of the substrate and the maximum inclined surface of the convex portion was 47°.

### 2. Sample Manufacturing

A buffer layer, an n-type semiconductor layer, a light emitting layer and a p-type semiconductor layer were formed in corresponding order on the sapphire substrate. Then, the laminated body having the semiconductor layer deposited thereto and the support substrate were soldering-bonded. After that, the sapphire substrate was separated from the laminated body. Then, the surface of the exposed n-type semiconductor layer was cleaned with the HCl aqueous solution and the n-type semiconductor layer was then etched with the TMAH solution. Also, a p-type electrode and an n-type electrode were formed.

In the meantime, a sample (an embodiment 1) having no fluorescent material containing glass layer and samples (embodiments 2 and 3) having a fluorescent material containing glass layer were manufactured. Also, for comparison, a sample (a comparative example 1) in which the n-type semiconductor layer is not provided with the fine irregularity was manufactured.

### 3. Test Result

### 3-1. A Case Where No Fluorescent Material Containing Glass Layer Was Formed

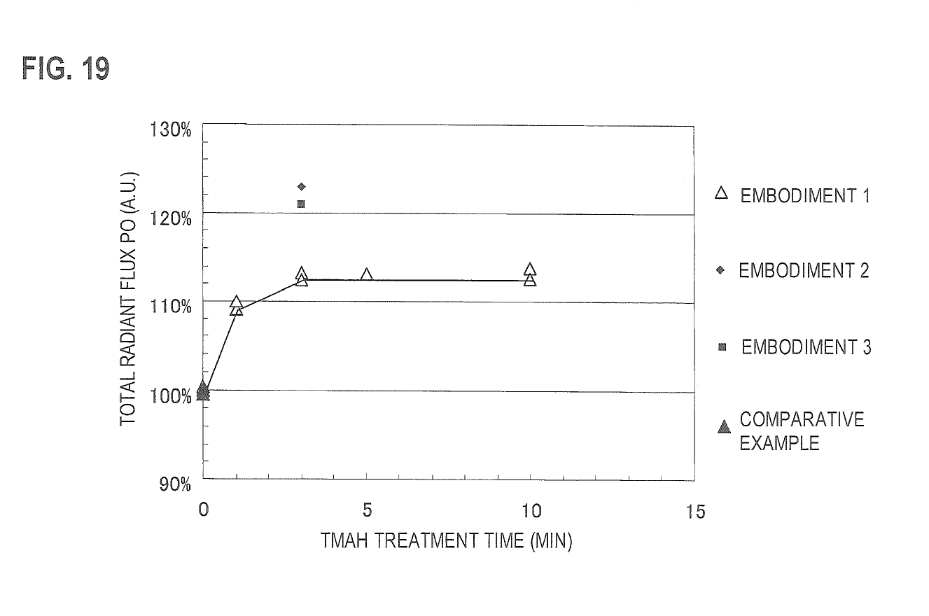

A test result is shown in FIG. 19. In FIG. 19, a horizontal axis indicates time for which the light emitting element was immersed into the TMAH solution and a vertical axis indicates a total radiant flux. Here, the total radiant flux of the light emitting element that has not been immersed into the TMAH solution yet was set to be 100%. That is, the total radiant flux of the light emitting element in which the irregularity corresponding to the irregularity shape of the irregularity substrate was formed but the fine irregularity was not formed was set to be 100%.

As shown in FIG. 19, the total radiant flux of the light emitting element was increased over the immersion time in the TMAH solution. When three minutes has elapsed, the value of the total radiant flux of the light emitting element was saturated. That is, it is possible to implement the sufficient fine processing by immersing the light emitting element in the TMAH solution for three minutes or longer. As shown in FIG. 19, the total radiant flux of the light emitting element was improved by about 13% when the immersion time in the TMAH solution was three minutes or longer and ten minutes or shorter.

### 3-2. A Case Where Fluorescent Material Containing Glass Layer Was Formed

Also, a case where the fluorescent material containing glass layer was formed is shown in FIG. 19. As shown in FIG. 19, the value of the total radiant flux was larger in the light emitting element having the fluorescent material containing glass layer. A table 1 summarizes the above results.

TABLE 1

| | | | | total |
|---|---|---|---|---|
| | | | | radiant |
| | fine processing | glass layer | refractive index | flux |
| embodiment 1 | Yes | No | — | 113% |
| embodiment 2 | Yes | Yes | 1.57 | 122% |
| embodiment 3 | Yes | Yes | 1.41 | 120% |
| comparative | No | No | — | 100% |
| example 1 | | | | |

The embodiment 1 corresponds to the first illustrative embodiment. The light emitting element of the embodiment 1 was subject to the fine processing but was not formed with the fluorescent material containing glass layer. The total radiant flux of the embodiment 1 was 113%.

The embodiment 2 corresponds to the second illustrative embodiment. The light emitting element of the embodiment 2 was subject to the fine processing and was formed with the fluorescent material containing glass layer. The refractive index of the fluorescent material containing glass layer was 1.57. The total radiant flux of the embodiment 2 was 122%.

The embodiment 3 was substantially the same as the embodiment 2. However, the embodiment 3 was different from the embodiment 2 as regards the refractive index. The refractive index of the fluorescent material containing glass layer was 1.41. The total radiant flux of the embodiment 3 was 120%.

The comparative example 1 was not subject to the fine processing and was not formed with the fluorescent material containing glass layer. The total radiant flux of the comparative example 1 was 100%.

What is claimed is:

1. A method of manufacturing a group-III nitride semiconductor light emitting element, the method comprising:
a first irregularity shape part forming process of sequentially forming an n-type semiconductor layer, a light emitting layer and a p-type semiconductor layer on an irregularity substrate to make a laminated body and forming a first irregularity shape part on the n-type semiconductor layer;
a first irregularity shape part exposing process of separating the irregularity substrate from the laminated body to expose the first irregularity shape part of the n-type semiconductor layer; and
a second irregularity shape part fainting process of roughening a surface of the first irregularity shape part of the n-type semiconductor layer to form a second irregularity shape part having fine irregularity on the first irregularity shape part.

2. The method according to claim 1, wherein the first irregularity shape part has a flat part and an inclined part, and
wherein the second irregularity shape part forming process includes forming fine irregularity on both the flat part and the inclined part.

3. The method according to claim 1, further comprising:
a fluorescent material containing glass layer forming process of forming a fluorescent material containing glass layer on the first irregularity shape part of the n-type semiconductor layer, and
a third irregularity shape part forming process of roughening a surface of the fluorescent material containing glass layer to form a third irregularity shape part on the fluorescent material containing glass layer.

4. The method according to claim 1, wherein the second irregularity shape part forming process includes roughening the first irregularity shape part by wet etching.

5. The method according to claim 4, wherein the second irregularity shape part forming process includes etching the first irregularity shape part by a TMAH solution or KOH solution.

6. The method according to claim 1, wherein the first irregularity shape part forming process includes forming a plurality of concave portions, which corresponds to a plurality of convex portions of a convex shape substrate, on the n-type semiconductor layer, and
wherein the first irregularity shape part exposing process includes exposing the multiple concave portions of the n-type semiconductor layer.

7. The method according to claim 1, wherein the first irregularity shape part exposing process includes removing the irregularity substrate by a laser liftoff method.

8. The method according to claim 1 further comprising a cleaning process of cleaning the surface of the first irregularity shape part by an HCl solution,
wherein the cleaning process is performed before the second irregularity shape part forming process.

9. A method of manufacturing a mounting body of a group-III nitride light emitting element comprising:
the first irregularity shape part forming process, the first irregularity shape part exposing process and the second irregularity shape part forming process according to of claim 1, and
a mounting process of mounting the laminated body on a sub-mount to make a mounding body,
wherein after the mounting process, the first irregularity shape part exposing process and the second irregularity shape part forming process are performed.

10. A group-III nitride semiconductor light emitting element comprising:
an n-type semiconductor layer;
a light emitting layer; and
a p-type semiconductor layer,
wherein the n-type semiconductor layer includes a first irregularity shape part having a flat part and an inclined part, and
wherein the first irregularity shape part has a second fine irregularity shape part on both the flat part and the inclined part.

11. The group-III nitride semiconductor light emitting element according to claim 10, wherein a fluorescent material containing glass layer is provided on the first irregularity shape part and the second irregularity shape part of the n-type semiconductor layer, and
wherein the fluorescent material containing glass layer has a third roughened irregularity shape part.
